(19) United States
(12) Patent Application Publication
(10) Pub. No.: US 2015/0303338 A1
(43) Pub. Date: Oct. 22, 2015

(54) BACKSHEET

(71) Applicant: LG CHEM, LTD., Seoul (KR)

(72) Inventors: Yoon Kyung KWON, Daejeon (KR); Hyun Cheol KIM, Daejeon (KR); Hyun Seong KO, Daejeon (KR)

(73) Assignee: LG CHEM, LTD., Seoul (KR)

(21) Appl. No.: 14/648,519

(22) PCT Filed: Dec. 6, 2013
(86) PCT No.: PCT/KR2013/011305

§ 371 Date: May 29, 2015

(30) Foreign Application Priority Data
Dec. 6, 2012 (KR) 10-2012-0141353
Dec. 6, 2013 (KR) 10-2013-0151367

(51) Int. Cl. H01L 31/049; B05D 3/12; C09J 167/00; B05D 5/00; C09J 175/04; H01L 31/048; B05D 7/00

(52) U.S. Cl. CPC H01L 31/049; H01L 31/0481; B05D 3/12; B05D 7/54; B05D 5/00; C09J 175/04; C09J 167/00; C09J 2475/003; C09J 2467/003

(57) ABSTRACT

There are provided a backsheet, a method of manufacturing the same, and a photovoltaic module including the same. In the present application, there is provided a backsheet, which exhibits excellent reliability and adhesive strength under extreme heat and/or humidity conditions, thereby improving weatherability and durability. Such a backsheet can be applied for a photovoltaic module, for example.

### BACKGROUND

1. Field of the Invention

The present application relates to a backsheet, a method of manufacturing the same, and a photovoltaic module including the same.

2. Discussion of Related Art

As a result of global environmental problems, the exhaustion of fossil fuels, and the like, there is a growing interest in and demand for new renewable energy and clean energy. Among them, solar energy receives attentions as representative clean energy sources that are capable of solving the problem of environmental pollution and the problem of the exhaustion of fossil fuels.

A photovoltaic cell applied with the principle for sunlight generation is a device for converting sunlight into electrical energy, and is prepared in a unit type by performing various functions of packaging for protecting a cell because such a device should be exposed to external environment for a long period of time so as to easily absorb sunlight. Such a unit is called photovoltaic modules.

In general, photovoltaic modules are made by using a backsheet having excellent weatherability and durability so as to stably protect a photovoltaic cell even in a state of being exposed in external environment for a long period of time. Examples of such a backsheet generally include a backsheet laminated with a resin layer including a fluorine resin such as polyvinyl fluoride (PVF) on a substrate.

However, since the PVF resin has poor adhesive strength to a polyethylene terephthalate (PET) film that is typically used as a substrate for a backsheet, a fluorine-based polymeric film obtained by extruding or casting is laminated to a substrate using a urethane-based adhesive, and then is in use. However, such a method requires high-priced equipment for preparing a fluorine-based polymeric film, further needs an adhesive coating process and a lamination process, and also should use a thick fluorine-based polymeric film.

There is a method using a resin layer including a fluorine resin, in which the resin layer is prepared in a resin suspension or solution and coated to a substrate. However, since such a method typically uses a solvent having a high boiling point, it requires a high drying temperature of 200° C. or higher. A great amount of energy is needed to provide such a high drying temperature, thereby increasing manufacturing costs of a backsheet of photovoltaic modules and also deteriorating qualities such as mechanical properties of a product because it is vulnerable to a thermal shock and problems such as thermal deformation are caused.

### CITATON LIST

### Patent Document

Patent Document 1: Korean Patent Application No. 2011-0034665
Patent Document 2: Korean Patent Application No. 2011-0031375

### SUMMARY OF THE INVENTION

The present invention is directed to a backsheet, a method of manufacturing the backsheet, and a photovoltaic module including the same.

The present application relates to a backsheet. Examples of the backsheet may include a substrate layer, an intermediate layer, and a fluorine resin layer which are laminated in order.

The backsheet may have excellent adhesive strength between layers and superior durability. For example, when the backsheet is maintained in conditions of 2 atm, 121° C., and 100% relative humidity for 75 hours or 100 hours, and then is subjected to a cross-cut test according to ASTM D3002/D3359, a delamination area thereof may be 15% or less, 10% or less, or 5% or less with respect to the total area. The cross-cut test may be performed after maintaining a backsheet before being applied to a product after being manufactured in such conditions for 75 hours or 100 hours, and for example, may be performed on a side of a fluorine resin layer in a way defined in the following Examples. The backsheet exhibiting excellent adhesive strength as described above may be manufactured by forming an intermediate layer including an aqueous dispersion binder to be described below in an inline-coating way, and if necessary, forming a layer including a fluorine resin having a predetermined degree of crystallinity thereon. As the delamination area described above is small, the backsheet exhibits excellent durability. The lowest limit thereof is not intended to be limited, and for example, may be 0%.

FIG. 1 is a cross-sectional diagram of an exemplary backsheet. As illustrated in FIG. 1, a backsheet 10 may include a substrate layer 13; an intermediate layer 12 formed on the substrate layer 13; and a fluorine resin layer 11 formed on the intermediate layer 12.

The intermediate layer 12 is for securing adhesive strength between the fluorine resin layer 11 and substrate layer 13, and in other examples, may be called a compatible polymer layer or an inline coating layer. The term “compatible polymer layer” may mean a layer including components of a fluorine resin layer and components having excellent compatibility, and the term “inline coating layer” may mean a layer formed in an inline coating way. In this way, the backsheet exhibiting excellent durability as described above can be provided by forming an intermediate layer in an inline way using a compatible polymer.

For example, the intermediate layer may include an aqueous dispersion binder, and thus may be an inline coating layer including the aqueous dispersion binder. For example, the aqueous dispersion binder is a crosslinkable aqueous dispersion binder, that is, an aqueous dispersion binder capable of crosslinking, and the intermediate layer may further include a crosslinking agent.

The film according to another example of the present application may have an intermediate layer and a resin layer formed on other side of the substrate layer, and thus may include the intermediate layer and the resin layer which are formed in order on both sides of the substrate layer.

A specific type of the substrate layer is not particularly limited, and it is possible to appropriately select from various materials that are known in the art according to required functions or uses, and then to use. In one example, the substrate layer may be various metal films or polymer films. The metal films may include a film consisting of general metal components according to use. Examples of the polymer films may include a single sheet such as an acrylic film, a polyolefin film, a polyamide film, a polyurethane film, or a polyester film, a laminated sheet prepared by laminating one or two or more one among them, or a co-extruded product prepared by using the resin. In general, a polymer film, for example, a polyester film is used as the substrate layer, but is not intended to be limited. Examples of the polyester film may include a poly(ethylene terephthalate) (PET) film, a poly(ethylene naphthalate) (PEN) film, or a poly(butylene terephthalate) (PBT) film. When the polyester film is used, in consideration of the anti-hydrolysis property of a backsheet, for example, the polyester film having a low content of oligomer generated during condensation polymerization is selected and used, or the polyester film is further subjected to a thermal treatment in order to improve the known anti-hydrolysis property, thereby decreasing a water content of the polyester and contraction percentage, such that the anti-hydrolysis property can be further improved.

A functional group, for example, a carboxyl group, an aromatic thiol group, and a phenolic hydroxyl group may be included on one side or both sides of the substrate layer. In this case, since a covalent bond between the substrate layer and the intermediate layer is increased, interface binding force can be further improved. A functional group on a surface of the substrate layer may be induced through at least one surface treatment selected from, for example, high frequency spark discharge treatment such as plasma treatment and corona treatment; primer treatment, anchoring agent treatment; coupling agent treatment; deposition treatment; flame treatment; chemical activation treatment using a gaseous phase Lewis acid (for example, BF₃), a sulfuric acid, a high-temperature sodium hydroxide, or the like; and thermal treatment. As the surface treatment method, any of the means that are generally known and widely used in the art may be used without limit as long as the means can induce the functional groups described above on a surface of the substrate layer.

A thickness of the substrate layer is not particularly limited, and as necessary, may be appropriately controlled and then used. For example, the thickness thereof may be within a range of about 50 μm to 500 μm, or about 100 μm to 300 μm. When the thickness of the substrate layer is controlled within the range as described above, it is possible to excellently maintain electric insulation, barrier property against water, mechanical property, handling property, and the like for the backsheet having the thickness.

As one example, the intermediate layer may include an aqueous dispersion binder. The intermediate layer is formed by inline coating using the aqueous dispersion binder, and thus adhesive strength to the fluorine resin layer to be formed on the intermediate layer can be improved.

A type of the aqueous dispersion binder, for example, a crosslinkable aqueous dispersion binder is not particularly limited, and can be used without limit as long as the aqueous dispersion binder has excellent compatibility with the fluorine resin to be described below. Examples of the aqueous dispersion binder may include at least one selected from the group consisting of polyurethane, a silane-modified urethane resin, an acrylic resin, polyurea, polyamide, polyolefin, polyvinylacetate, polyether, an alkyd resin, a urethane-acrylate copolymer, a vinyl-urethane copolymer, an ethylene-vinylalcohol copolymer, a silicon-acrylic-urethane copolymer, an ethylene-vinylacetate copolymer, and an acrylic-modified polyester, but is not limited thereto. For example, when using a silane-modified urethane resin, polyurea, polyamide, a vinyl-urethane copolymer, or an acrylic-urethane copolymer, a crosslinking structure is formed between binders, and thus crosslinkability can be improved. Other examples of the crosslinkable aqueous dispersion binder may include one prepared by introducing a crosslinkable functional group necessary for an aqueous dispersion binder without a crosslinkable functional group as a side chain through graft polymerization, or the like. In this case, examples of the crosslinkable functional group to be grafted to the aqueous dispersion binder may include a hydroxyl group, a carboxyl group, a cyano group, an epoxy group, a sulfonic acid group, an amine group, and the like, but is not limited thereto.

The intermediate layer may further include a crosslinking agent, and thus durability or adhesive strength between the substrate layer and resin layer can be improved. For example, the crosslinking agent included in the intermediate layer allows adhesive strength between the substrate layer and resin layer to improve, and also forms a crosslinking structure of the aqueous dispersion binder, thereby providing a more dense internal structure.

Examples of the crosslinking agent may include at least one selected from the group consisting of an isocyanate crosslinking agent, an oxazoline crosslinking agent, a carbodiimide crosslinking agent, and an aziridine crosslinking agent. The crosslinking agent may form an interpenetrating crosslinked structure by binding with the aqueous dispersion binder or may allow to further improve interface adhesive strength by reacting with a hydroxyl group or a carboxyl group on a surface of the substrate layer.

Examples of the isocyanate crosslinking agent may include tolylene diisocyanate (TDI), diaryl isocyanate, diphenylmethane-4,4′-diisocyanate, diphenylmethane-2,4′-diisocyanate, xylene diisocyanate (XDI), meta xylene diisocyanate, hexamethylene-1,6-diisocyanate (HDI), 1,6-diisocyanate hexane, adducts of tolylene diisocyanate and hexanetriol, adducts of tolylene diisocyanate and trimethylol propane, polyol-modified diphenylmethane-4,4′-diisocyanate, carbodiimide-modified diphenylmethane-4,4′-diisocyanate, isophorone diisocyanate (IPDI), 1,5-naphtalene diisocyanate, 3,3′-bitolylene-4,4′-diisocyanate, 3,3′-dimethyldiphenylmethane-4,4′-diisocyanate, meta phenylene diisocyanate, and the like. The oxazoline crosslinking agent may be used without limit as long as it includes an oxazoline group-containing monomer, or a compound having an oxazoline group as a functional group, for example, a polymer compound that includes one or more kinds of the monomers and is copolymerized with one or more kinds of other monomers. Examples of the oxazoline crosslinking agent may include a compound such as 2-vinyl-2-oxazoline, 2-vinyl-4-methyl-2-oxazoline, 2-vinyl-5-methyl-2-oxazoline, 2-isoprophenyl-2-oxazoline, 2-isoprophenyl-4-methyl-2-oxazoline, or 2-isoprophenyl-5-ethyl-2-oxazoline, or a polymer compound prepared by polymerizing one or two or more kinds among them. The polymer compound may be copolymerized with other comonomer. Examples of the comonomer may include at least one selected from the group consisting of alkyl(meth)acrylate, an amide group-containing monomer, a unsaturated nitrile-based monomer, a vinyl ester-based monomer, a vinyl ether-based monomer, a halogen-containing α,β-unsaturated monomer, or a α,β-unsaturated aromatic monomer. Examples of the aziridine crosslinking agent may include N,N′-toluene-2,4-bis(1-aziridinecarboxide), N,N′-diphenylmethane-4,4′-bis(1-aziridinecarboxide), triethylene melamine, bisisoprotaloyl-1-(2-methylaziridine), and tri-1-aziridinylphosphine oxide. The carbodiimide crosslinking agent may include a carbodiimide compound or a polycarbodiimide, but is not limited thereto. In general, the carbodiimide compound has the structure represented by the following Chemical Formula 1, and the polycarbodiimide includes a repeated structure like the following Chemical Formula 2.

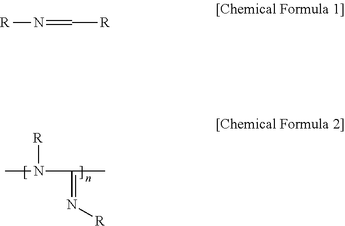

In the above Chemical Formulas 1 and 2, R represents a known functional group that may be included in a carbodiimide compound or polycarbodiimide, and n represents an arbitrary number.

As the crosslinking agent, in addition to the crosslinking agents as exemplified above, a melamine-based resin or an epoxy-based resin may be selectively and additionally used, and in this case, it is possible to lower a curing temperature and improve adhesion performance. Examples of the melamine-based crosslinking agent may include melamine, a methylolated melamine derivative obtained by condensing melamine and formaldehyde, a compound that is partially or completely etherified by reacting methylolated melamine and lower alcohol, and a mixture thereof. The epoxy-based crosslinking agent is a crosslinking agent including an epoxy group in its molecular, and examples thereof may include at least one selected from the group consisting of ethyleneglycol-diglycidyl ether, polyethyleneglycol-diglycidyl ether, polyglycerol polyglycidyl ether, triglycidyl ether, trimethylol propane triglycidyl ether, N,N,N′,N′-tetraglycidyl ethylene diamine, glycerin diglycidyl ether, propyleneglycol-diglycidyl ether, and polypropyleneglycol-diglycidyl ether.

As one example, the crosslinking agent may be used in a ratio of 1 part by weight to 300 parts by weight with respect to 100 parts by weight of an aqueous dispersion binder. In the present specification, a unit “part by weight” may represent a ratio of weight. As other example, the crosslinking agent may be used in a ratio of 5 parts by weight or more or 8 parts by weight or more with respect to 100 parts by weight of the binder within the range described above. In addition, as other example, the crosslinking agent may be used in a ratio of 250 parts by weight or less, 200 parts by weight or less, 150 parts by weight or less, 100 parts by weight or less, or 80 parts by weight or less with respect to 100 parts by weight of the binder within the range described above. A crosslinking density of the intermediate layer can be appropriately controlled within the range described above, proper adhesive strength with the substrate layer can be secured, and also coating physical properties such as coatability, stretchability, blocking property, and yellowing property can be improved.

The intermediate layer may further include a general additive, such as a surfactant, an UV stabilizer, a thermal stabilizer, or barrier particles, as necessary.

A thickness of the intermediate layer is not particularly limited, but for example, 10 nm or more. For example, the thickness of the intermediate layer may be about 10 nm to 1,000 nm, 20 nm to 500 nm, 50 nm to 300 nm, or 100 nm to 300 nm, and may be adjusted within the above range, thereby improving adhesive strength of the intermediate layer and maintaining excellent weatherability and durability of the intermediate layer. However, the thickness of the intermediate layer is not limited to the above range, but can be appropriately controlled as necessary.

The backsheet may include a fluorine resin layer on—the intermediate layer. The term “fluorine resin layer” may mean a layer including a fluorine resin.

Examples of the fluorine resin may include, for example, one having a proper degree of crystallinity. Using such a resin, the generation of an undesirable binding such as an urethane binding by a reaction with a crosslinking agent of the intermediate layer can be minimized. When the urethane binding is formed, good initial adhesive strength may be exhibited, but durability and adhesive strength could be disadvantaged under a high-temperature and humidity condition. Examples of the fluorine resin may include a resin having a degree of crystallinity of about 55% or less, 50% or less, 10% to 55%, 20% to 55%, 30% to 55%, or 40% to 50%. In the present specification, the term “a degree of crystallinity” means percentage (with respect to weight) of a crystalline area in the fluorine resin, and can be measured using a known way, such as a differential scanning calorimetry analysis. As one example, the degree of crystallinity of the fluorine resin can be controlled by disarranging a regular element array of the fluorine resin through copolymerization of a comonomer at the time of preparing the fluorine resin, or polymerizing the fluorine resin in a type of a branched polymer.

As one example, the fluorine resin may be a pure non-functionalized fluorine resin. The pure non-functionalized fluorine resin may have excellent weatherability as compared with a functionalized fluorine resin, for example, an acrylic-modified fluorine resin, a crosslinkable terminal group-containing fluorine resin, and the like. Examples of the pure non-functionalized fluorine resin may include a thermoplastic fluorine resin without a crosslinkable functional group, and may provide an effect exhibiting excellent adhesive reliability as compared with a fluorine-based non-crystalline thermosetting resin including a crosslinkable functional group.

The fluorine resin may have a weight average molecular weight of about 50,000 to 1,000,000. In the present specification, the weight average molecular weight is a conversion numerical value of standard polystyrene measured with a gel permeation chromatograph (GPC). The weight average molecular weight of the fluorine resin is not particularly limited, and for example, may be appropriately controlled in consideration of durability of a film or solubility of the fluorine resin as a solvent during a preparation process.

A melting point of the fluorine resin may be about 80° C. to 175° C. or 120° C. to 165° C. The melting point of the fluorine resin may be selected in consideration of deformation possibility at the time of using a backsheet or solubility as a solvent during a preparation process.

Examples of the fluorine resin may include homopolymer, copolymer, or a mixture thereof, which includes a polymerization unit derived from at least one or two monomers selected from the group consisting of polyvinylidene fluoride (VDF), polyvinyl fluoride (VF), tetrafluoroethylene (TFE), hexafluoropropylene (HFP), chlorotrifluoro ethylene (CTFE), trifluoro ethylene, hexafluoroisobutylene, perfluoro(butylethylene), perfluoro(methylvinylether) (PMVE), perfluoro(ethylvinylether) (PEVE), perfluoro(propylvinylether) (PPVE), perfluoro(hexylvinylether) (PHVE), perfluoro-2,2-dimethyl-1,3-dioxol (PDD), and perfluoro-2-methylene-4-methyl-1,3-dioxolane (PMD).

The fluorine resin may be a homopolymer including a polymerization unit derived from polyvinylidene fluoride (VDF) or polyvinyl fluoride (VF), a copolymer with comonomers which are different therefrom, or a mixture including at least two types among them. Examples of the fluorine resin may include poly(vinylidene fluoride) (PVDF) or poly(vinyl fluoride) (PVF) including a polymerization unit derived from at least one or two comonomers selected from olefin fluoride, alkyl vinyl ether fluoride, perfluoro-2,2-dialkyl-1,3-dioxol, and perfluoro-2-alkylene-4-alkyl-1,3-dioxolane, along with a polymerization unit derived from polyvinylidene fluoride (VDF) or polyvinyl fluoride (VF). In this regard, olefin may be alpha olefin having 2 to 20 carbon atoms, 2 to 16 carbon atoms, 2 to 12 carbon atoms, 2 to 8 carbon atoms, or 2 to 4 carbon atoms, and alkyl or alkylene may be alkyl or alkylene having 1 to 20 carbon atoms, 1 to 16 carbon atoms, 1 to 12 carbon atoms, 1 to 8 carbon atoms, or 1 to 4 carbon atoms. Examples of the olefin fluoride may include tetrafluoroethylene (TFE), hexafluoropropylene (HFP), chlorotrifluoroethylene (CTFE), trifluoroethylene, hexafluoroisobutylene, or perfluorobutylethylene. Examples of the alkyl vinyl ether fluoride may include perfluoro(methylvinylether) (PMVE), perfluoro(ethylvinylether) (PEVE), perfluoropropylvinylether (PPVE), or perfluorohexylvinylether (PHVE). Examples of the perfluoro-2,2-dialkyl-1,3-dioxol or perfluoro-2-alkylene-4-alkyl-1,3-dioxolane may include perfluoro-2,2-dimethyl-1,3-dioxol (PDD) or perfluoro-2-methylene-4-methyl-1,3-dioxolane (PMD). However, the present invention is not limited thereto.

A ratio of comonomer included in poly(vinylidene fluoride) (PVDF) or poly(vinyl fluoride) (PVF) or a polymerization unit derived therefrom is not particularly limited, but for example, may be about 0.5 wt % to 50 wt %, 1 wt % to 40 wt %, 7 wt % to 40 wt %, 10 wt % to 30 wt %, or 10 wt % to 20 wt %. In the range as described above, it is possible to secure durability and weatherability of a backsheet, to induce effective inter-diffusion effect and low temperature drying, and also further to improve adhesive strength.

As one example, the fluorine resin layer may further include various additives such as a pigment, a filler, an UV stabilizer, or a thermal stabilizer, in addition to the fluorine resin. At this time, examples of an available pigment or filler may include metal oxide materials such as titanium dioxide, silica, or alumina, a black pigment such as calcium carbonate, barium sulfate, or carbon black, or pigment components exhibiting other colors, but the present invention is not limited thereto. The pigment or the filler as described above may act on additional improvement of the adhesive strength of a resin layer by an inherent functional group which is included in each component, along with an inherent effect of controlling a color or opacity of the resin layer. The UV stabilizer, the thermal stabilizer, or the barrier particles may include a general component that is known in the art. The contents of other additives, such as the pigment or the filler may be 60 wt % or less with respect to solid content of the fluorine resin, but the present invention is not limited thereto.

A thickness of the resin layer including the fluorine resin may be, but is not particularly limited to, for example, 3 μm to 50 μm or 10 μm to 30 μm. In a case where the thickness of the resin layer including the fluorine resin is controlled in the range described above, it is possible to improve a light-blocking property and prevent manufacturing cost increase.

The fluorine resin layer may be a coating layer. The term “coating layer” used in the present specification means a resin layer formed by a coating way. More specifically, the “coating layer” means a case where a sheet prepared by a casting method or an extrusion way is formed by using the way in which a composition prepared by dissolving components comprising each layer in a solvent is coated on a coating surface, not using a laminating way using an adhesive.

As one example, in a case where the fluorine resin layer is formed by using a coating way, it may be easier to form interpenetrating polymer networks (IPN) through penetrating the fluorine resin into an intermediate layer that is formed on a lower part using an inline coating way. In addition, a C—F₂ binding dipole of the fluorine resin, an aqueous dispersion binder of the intermediate layer, and a functional group included in a crosslinking agent improve interaction between dipole moments through a van der Waals binding, thereby improving adhesive strength and mechanical property on a contact interface, and also improving durability and weatherability.

The present application relates to a method of preparing the backsheet described above. The method may include, for example, forming an intermediate layer on a substrate layer using an inline coating way and forming a fluorine resin layer on the intermediate layer. As described above, the fluorine resin layer may be formed by using a coating way.

The intermediate layer may be formed by using an inline coating way in the preparation process of a substrate layer, and thereby it is possible to provide a backsheet having excellent adhesive strength and durability. The inline coating way may include, for example, elongating the substrate layer in one direction in a state of forming a layer of an aqueous dispersion composition including an aqueous dispersion binder on one side of the substrate layer.

For example, the layer of aqueous dispersion composition may be formed by coating the aqueous dispersion composition mixed with the aqueous dispersion binder described above and if necessary, other additives such as a crosslinking agent on the substrate layer.

The aqueous dispersion composition may be prepared by dissolving or dispersing the components described above in an aqueous solvent, for example, water. The aqueous dispersion composition may include an aqueous dispersion binder, a crosslinking agent, and an aqueous solvent.

In order to prepare the aqueous dispersion composition, a method of dispersing various components described above in a proper aqueous solvent is not particularly limited, and may be used without limit as long as it is generally and widely used in the art. As one example, the aqueous dispersion composition may further include a surfactant, and thus prevent decrease of dispersibility and wettability. Therefore, decrease of weatherability can be prevented while the intermediate layer is uniformly coated. The surfactant may be present in a state of being included at the time of preparing the aqueous dispersion binder. In addition, the aqueous dispersion composition may include, in a dispersing form, additives capable of being included in the intermediate layer described above within the range without deteriorating physical properties of the intermediate layer.

As a method of coating the aqueous dispersion composition, various known coating methods may be applied without limit as long as they can be applied for an inline process. Examples of the coating method may include known printing ways such as an offset printing method or a gravure printing method, or known coating ways such as a roll coat, a knife edge coat, or a gravure coat.

The substrate layer may be elongated in a state of forming the layer of aqueous dispersion composition. In the present specification, “an elongation process of a substrate layer” may mean, for example, a process of pulling the substrate layer in a mechanical direction (MD) or a transverse direction (TD) after the process of forming a non-elongated substrate layer through cooling and solidification of a melted and extruded resin of the substrate layer on a cast roll.

The conditions for the elongation described above are not particularly limited. For example, an elongation ratio of the substrate layer may be about 1.5 times to 10 times, about 1.5 times to 8 times, about 1.5 times to 6 times, or about 2 times to 5 times, and an elongation temperature of the substrate layer may be appropriately selected in consideration of progress efficiency and the like.

If necessary, the substrate layer formed with the aqueous dispersion composition may be further subjected to a proper drying process before being applied for an elongation process. The drying conditions are not particularly limited, and for example, the drying may be performed at a temperature of 200° C. or less or 100° C. to 180° C. for 10 seconds to 30 minutes or 1 minute to 10 minutes.

As one example, the substrate layer having the layer of the aqueous dispersion composition may be a uniaxial elongation substrate layer, and the substrate layer may be elongated in a direction that is perpendicular to the uniaxial elongation. In other words, for example, before forming the layer of the aqueous dispersion composition, the substrate layer may be elongated in the MD direction or TD direction, then be formed with the layer of the aqueous dispersion composition, and then again be elongated in the direction that is perpendicular to the elongation direction, for example, in the TD direction or MD direction. The conditions for the elongation of the substrate layer performed before forming the aqueous dispersion composition are not particularly limited, and the above-described contents may be similarly applied.

For example, the non-elongated substrate layer may be uniaxially elongated in a desired elongation ratio in a mechanical direction (or a transverse direction) by a roll heated at a proper temperature, for example, about 100° C. to 200° C., be cooled using a roll of a proper temperature, for example, about 50° C. to 100° C., and be formed with the layer of the aqueous dispersion composition, and the both ends of the substrate layer may be again elongated in a desired ratio in the direction that is perpendicular to the uniaxial elongation at a proper temperature, for example, about 100° C. to 200° C. using an elongation system in a roll or tender way. If necessary, besides a sequential elongation method, in which the uniaxial elongation and vertical axis elongation are separately performed, as another example, the method including applying the aqueous dispersion composition to the substrate layer and then performing the uniaxial elongation and vertical axis elongation at the same time may be applied.

In the above method, a relaxation process may be further performed after the elongation process. For example, the relaxation may be performed in the direction, in which the elongation is performed within the temperature ranging from about 150° C. to 250° C., for example, in the mechanical direction and/or the transverse direction, thereby improving dimensional stability of the substrate layer while not breaking aligned molecules and maintaining an anti-hydrolysis property. The range of the relaxation is not particularly limited, and for example, the relaxation process may be performed by contracting within the relaxation rate range of less than 30% in the mechanical and/or the transverse direction. The term “relaxation rate” means a value that is calculated by dividing the relaxed length by the dimension before being elongated.

After the elongation, a heat setting process may be performed by heating between the elongation process and the relaxation process. After the heat setting process, the relaxation process may be performed. The conditions for the heat setting are not particularly limited, and for example, there are a method of appropriately removing water in the substrate layer applied with the aqueous dispersion composition using an oven after the elongation, a method of heating the substrate layer applied with the aqueous dispersion composition during the elongation process, and the like. At this time, the process temperature may be about 150° C. to 350° C. and the time may be in the range of about 1 second to 60 seconds.

After forming an intermediate layer in the inline way as described above, a fluorine resin layer may be formed. The fluorine resin layer may be formed by coating, for example, a fluorine resin having a degree of crystallinity of 55% or less as described above and a composition including a solvent having a boiling point of 200° C. or less (hereinafter, sometimes referred to as “resin layer composition”) on the intermediate layer.

The composition for forming the resin layer may further include additives as described above. At this time, the additives may be dissolved in a solvent along with a fluorine resin and the like, respectively, or the additives may be mixed again with the solvent including the fluorine resin after being prepared in a mill base type, apart from the above components. A chemical interaction such as a van der Waals bond, a hydrogen bond, an ion bond, or a covalent bond may be generated by a functional group included in additives such as a filler or pigment dispersant, which may be included in the resin layer including the fluorine resin described above, and the adhesive strength between the resin layer and the substrate layer may be further improved by the above chemical interaction.

Examples of the solvent having a boiling point of 200° C. or less may include one or more types selected from the group consisting of acetone, methylethylketone (MEK), dimethylformamide (DMF), and dimethylacetamide (DMAC), but the present invention is not limited thereto. These solvents properly dissolve components forming the resin layer, such as the fluorine resin, and also since these solvents are easily evaporated at a temperature of 200° C. or less, they may be dried at a relatively low temperature after being applied on the substrate layer. In addition, in case of using the solvents, the interdiffusion of the fluorine resin included in the resin layer into the intermediate layer may be generated by swelling the surface of the intermediate layer at a contact interface at the time of contacting between the resin layer including the fluorine resin and the intermediate layer. For this reason, the physical and chemical adhesive strength between the resin layer and the intermediate layer is improved thereby further improving adhesive strength between the resin layer and the intermediate layer.

A method of coating the composition of the resin layer to the intermediate layer is not particularly limited, and for example, any methods, including for example, known printing ways such as an offset printing method and a gravure printing method, or known coating ways such as a roll coat, a knife edge coat, and a gravure coat, can be applied as long as the methods can form an uniform resin layer. In addition to the above methods, various ways that are known in the art can be applied.

As one example, after the process of coating the composition of the resin layer on the intermediate layer, subsequently, a process of drying the coated composition of the resin layer may be further performed. The conditions for drying is not particularly limited, and for example, the drying may be performed, for example, at a temperature of 200° C. or less, or 100° C. to 180° for 30 seconds to 30 minutes or for 1 minute to 10 minutes. By performing the drying process in the conditions as described above, it is possible to prevent an increase in preparing costs due to the high-temperature drying process of 200° C. or higher and also prevent product quality degradation due to heat deformation or heat shock.

As one example, the backsheet according to the present application may further include various functional layers that are known in the art if necessary. Examples of the functional layers may include an adhesive layer, an insulation layer, and the like. For example, in the backsheet, the above described intermediate layer and resin layer including the fluorine resin may be sequentially included on one side of the substrate layer and the adhesive layer and the insulation layer may be sequentially included on other side of the substrate layer. The adhesive layer or the insulation layer may be formed using various ways that are known in the art. The insulation layer may be a layer consisting of, for example, ethylene vinyl acetate (EVA) or low density linear polyethylene (LDPE). The layer consisting of the EVA or LDPE may have simultaneously the function as an insulation layer, the function for increasing adhesive strength with an encapsulant of a photovoltaic module, the function for reducing preparing costs, and the function for maintaining excellent re-workability.

The backsheet for a photovoltaic module according to the embodiments of the present application as described above includes an intermediate layer including an aqueous dispersion binder formed on a substrate layer and a fluorine resin layer formed on the intermediate layer, wherein the intermediate layer may form a chemical covalent bond with various functional groups on the surface of the substrate layer thereby providing excellent adhesive strength between the substrate layer and the intermediate layer. In addition, the aqueous dispersion binder in the intermediate layer may exhibit an interdiffusion effect with the fluorine resin included in the resin layer in the upper part of the intermediate layer thereby further improving adhesive strength between the intermediate layer and the resin layer. In addition, since there is the resin layer including the fluorine resin having excellent weatherability on the outermost layer of the backsheet, it is possible to improve durability and weatherability.

Specifically, during the process for manufacturing a backsheet for a photovoltaic module as described above, on the interface of the substrate layer and the intermediate layer or the interface of a surface treatment layer of the substrate layer and the intermediate layer, the aqueous dispersion binder included in the intermediate layer may be diffused into the substrate layer or the surface treatment layer of the substrate layer. For this reason, a chemical covalent bond between the substrate layer and the intermediate layer may be formed and also chain entanglement and van der Waals force between molecular chains may be generated, thereby improving adhesive strength. In addition, on the interface between the intermediate layer and the resin layer including the fluoride resin, the fluorine resin included in the resin layer may be diffused into the intermediate layer. For this reason, the chain entanglement and van der Waals force between molecular chains may be generated, thereby improving adhesive strength between the intermediate layer and the resin layer including the fluorine resin.

The intermediate layer may be formed in an inline coating process, and thus the intensity of the adhesive strength between the substrate layer and the intermediate layer may be more reinforced as compared with a case of forming the intermediate layer in an offline process.

As one example, a backsheet may be used for a photovoltaic module, for example, and has properties such as an insulating property and water blocking property in addition to durability and weatherability in order to stably protect a photovoltaic cell despite being exposed to an external environment for a long period of time.

In addition, the present application relates to a photovoltaic module including the backsheet. The structure of the photovoltaic module is not particularly limited as long as it includes the backsheet for a photovoltaic module, and various structures that are generally known in the art can be adopted without limit.

As one example, the photovoltaic module may include a transparent front substrate, a backsheet, and a photovoltaic cell encapsulated by an encapsulant or a photovoltaic array arranged in series or in parallel between the front substrate and the backsheet. As one example, the structure of the photovoltaic module may include a backsheet; a photovoltaic cell or photovoltaic array formed on the backsheet; a light-receiving sheet formed on the photovoltaic cell or photovoltaic array; and an encapsulant layer encapsulating the photovoltaic cell or the photovoltaic array between the backsheet and the light-receiving sheet.

The thickness of the backsheet is not particularly limited, and for example, may be 30 μm to 2,000 μm, 50 μm to 1,000 μm, or 100 μm to 600 μm. By controlling the thickness of the backsheet in the range of 30 μm to 2,000 μm, it is possible to construct a photovoltaic module in a more thin type and to maintain excellent physical properties such as weatherability.

A specific type of a photovoltaic cell to be formed on a backsheet is not particularly limited as long as it can generate photoelectron-motive force, and a photovoltaic device that is generally and widely used in the art can be used. Examples of the photovoltaic device may include a crystalline silicon photovoltaic cell such as a single-crystalline silicon photovoltaic cell and a multi-crystalline silicon photovoltaic cell, an amorphous silicon photovoltaic cell such as a single-junction photovoltaic cell or a tandem type photovoltaic cell, a group III-V semiconductor compound photovoltaic cell such as a gallium-arsenic (GaAs) and indium-phosphorus (InP) semiconductor compound photovoltaic cell, and a group II-VI semiconductor compound photovoltaic cell such as a cadmium-tellurium (CdTe) and copper-indium-selenide (CuInSe₂) semiconductor compound photovoltaic cell. In addition, a thin film multi-crystalline silicon photovoltaic cell, a thin film micro-crystalline silicon photovoltaic cell, and a hybrid photovoltaic cell consisting of a thin film crystalline silicon and amorphous silicon may be used.

A photovoltaic cell may form a photovoltaic array (photovoltaic assemblies) by wiring connecting between the photovoltaic cell and the photovoltaic cell. When the sunlight shines on the photovoltaic module, electrons (−) and holes (+) are generated inside the photovoltaic cell, and thus, currents flow through the wiring connecting the photovoltaic cell and the photovoltaic cell.

The light-receiving sheet formed on the photovoltaic cell or the photovoltaic array may protect the inside of the photovoltaic module from a rainstorm, an external shock, a fire, and the like and may perform a function of securing long-term reliability when the photovoltaic module is exposed to an external environment. A specific kind of the light-receiving sheet is not particularly limited as long as it has excellent light transmission property, electrical insulating property, mechanical, physical, or chemical strength, and the like. Examples of the light-receiving sheet may include a glass plate, a fluorine-based resin sheet, a cyclic polyolefin-based resin sheet, a polycarbonate-based resin sheet, a poly(meth)acrylic-based resin sheet, a polyamide-based resin sheet, a polyester-based resin sheet, and the like. According to one embodiment of the present application, a glass plate having excellent heat resistance can be used, but the present invention is not limited thereto.

The thickness of the light-receiving sheet is not particularly limited, and for example, may be 0.5 mm to 10 mm, 1 mm to 8 mm, or 2 mm to 5 mm. By controlling the thickness of the light-receiving sheet in the range of 0.5 mm to 10 mm, it is possible to construct the photovoltaic module in a more thin type, and also to maintain excellent physical properties such as long-term reliability of the photovoltaic module.

In addition, in the encapsulant layer encapsulating the inside of the photovoltaic module, more particularly, the photovoltaic cell or photovoltaic array between the backsheet and the light-receiving sheet, the encapsulants that are generally known in the art can be adopted without limit.

FIGS. 2 and 3 to be attached are diagrams illustrating cross-sectional diagrams of the photovoltaic modules according to various embodiments of the present application.

FIG. 2 is a cross-sectional diagram of a wafer-based photovoltaic module 20 including a backsheet for a photovoltaic module according to one example of the present application. As illustrated in FIG. 2, the photovoltaic module according to one example of the present application may generally include a light-receiving sheet 21 that may consist of a ferroelectric material (for example, glass); a backsheet 23 for a photovoltaic module according to examples of the present application; a photovoltaic device 24 such as the silicon-based wafer; and an encapsulant layer 22 encapsulating the photovoltaic device 24. In this configuration, the encapsulant layer 22 may include a first layer 22a that is attached to the light-receiving sheet 21 while encapsulating the photovoltaic device 24 and a second layer 22b that is attached to the backsheet 23 while encapsulating the photovoltaic device 24. The first layer and the second layer forming the encapsulant layer 22 may be formed with the materials that are generally known in the art, as described above.

FIG. 3 is a cross-sectional diagram of a thin film photovoltaic module 30 according to another embodiment of the present application. As illustrated in FIG. 3, in a case of the thin film photovoltaic module 30, a photovoltaic device 34 may be formed on a light-receiving sheet 31 that may generally consist of a ferroelectric material. The thin film photovoltaic device 34 described above may be generally deposited using a chemical vapor deposition (CVD) method, and the like. The photovoltaic module 30 of FIG. 3 may include an encapsulant layer 32 and a backsheet 33 like the photovoltaic module 20 of FIG. 2, and the encapsulant layer 32 may be formed in a single layer. A specific description of the encapsulant layer 32 and the backsheet 33 are as described above.

A method of manufacturing the various photovoltaic modules as described above is not particularly limited, and various methods can be adopted without limit as long as they are known in the art.

The photovoltaic modules illustrated in the attached FIGS. 2 and 3 are only examples among various embodiments of the photovoltaic module of the present application, and a structure of the module, and a type and a size of materials forming the modules are not particularly limited and any one that is generally known in the art can be used without limit as long as it includes the backsheet for a photovoltaic module according to the present application.

### Advantageous Effect

In the present application, there is provided a backsheet, which exhibits excellent reliability and adhesive strength under extreme heat and/or humidity conditions, thereby improving weatherability and durability. Such a backsheet can be applied for a photovoltaic module, for example.

### BRIEF DESCRIPTION OF THE DRAWINGS

FIG. 1 is a diagram illustrating a cross-sectional view of a backsheet according to one embodiment of the present application; and

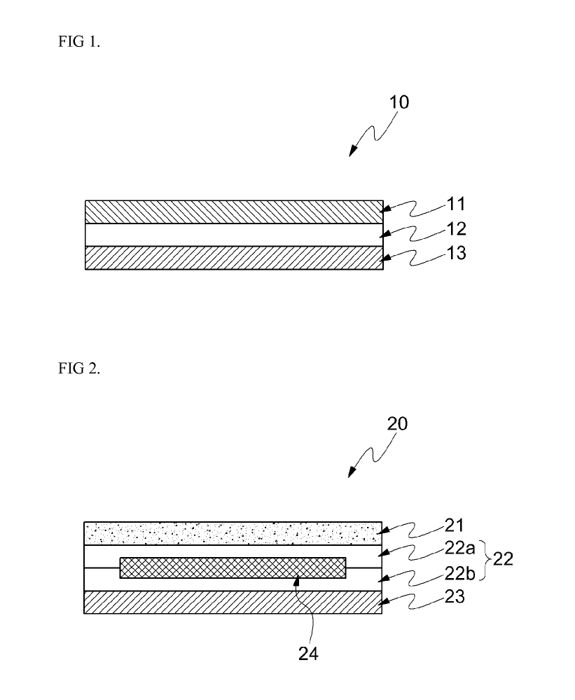

FIGS. 2 and 3 are diagrams illustrating cross-sectional views of photovoltaic modules according to one embodiment of the present application.

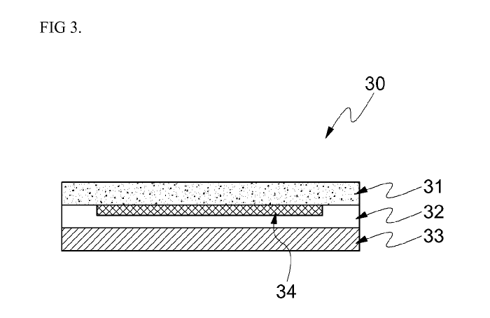

### DETAILED DESCRIPTION OF EXEMPLARY EMBODIMENTS

The present application will be described in detail below with reference to Examples according to the present application and Comparative Examples not according to the present application. However, the range of the present invention is not limited to the following Examples.

All the physical properties in Examples and Comparative Examples were measured as the following way.

1. 180° Peel Strength

A specimen (a backsheet) was cut in a width of 10 mm on the basis of ASTM D1897 standard, and peel strength thereof was measured with a peel speed of 4.2 mm/sec and peel angle of 180°.

2. Cross-Hatch Adhesion

A cross cut test was performed based on ASTM D3002/D3359. 100 square lattices having 1 mm in width and length, respectively, were formed by drawing 11 lines with a knife in vertical and horizontal directions, respectively at intervals of 1 mm on the fluorine resin layer of the specimen (the backsheet). Since then, a CT-24 adhesive tape manufactured by Nichiban Company was attached on the cut side, and then while peeling, a state of the side peeled along with the tape was measured, and evaluated as the following criteria:

<Evaluation Criteria>

5B: No peeled side

4B: less than 5% of the area of peeled side with respect to the total area

3B: 5% to 15% of the area of peeled side with respect to the total area

2B: more than 15% and 35% or less of the area of peeled side with respect to the total area

1B: more than 35% and 65% or less of the area of peeled side with respect to the total area

0B: more than 65% of the area of peeled side with respect to the total area

3. Pressure Cooker Test (PCT)

The backsheets (both sides of the substrate layer were coated with the intermediate layer and resin layer) for a photovoltaic module manufactured in Examples and Comparative Examples were maintained in an oven under the conditions of 2 atm, 121° C., and 100% of relative humidity (R.H.) for 25 hours, 50 hours, 75 hours, and 100 hours, and then the changes of the adhesive strength were observed.

4. Measurement of Degree of Crystallinity

The degree of crystallinity of the fluorine resin was measured using a differential scanning calorimeter. A heat of fusion (ΔHf) during second heating was measured using the differential scanning calorimeter, and a rate of heating was 10 K/min. A standard for measuring ΔHf was the area between the part of 80° C. and the part of 3° C. higher than that of the end part of a melting phase. Since ΔHf of 100% crystalline PVDF was 105 J/g, the degree of crystallinity was obtained from such a value. In case of a copolymer, the degree of crystallinity was calculated based on ΔHf of 100% crystalline PVDF.

Preparation of Fluorine Resin

The types of fluorine resin used in Examples and Comparative Examples are as listed in the following Table 1. In Table 1, a weight average molecular weight (Mw) of the fluorine resin was evaluated in a general way using a gel permeation chromatograph (GPC).

TABLE 1

| | | Monomer | Degree of | Molecular | Melting |
|---|---|---|---|---|---|
| | | ratio | crystallinity | weight | point |
| Fluorine Resin | | (Monomer) | (%) | (M_{w}) | (° C.) |
| A | VDF-CTFE | 85:15 | 23 | 270,000 | 166 |
| | Copolymer | (VDF:CTFE) | | | |
| B | PVDF | 100 | 44 | 550,000 | 160 |
| | | (VDF) | | | |

Monomer ratio unit: part by weight
VDF: Vinylidene Fluoride
CTFE: Chlorotrifluoroethylene
VDF-CTFF: Copolymer of VDF and CTFE
PVDF: poly(vinylidene fluoride)

### Example 1

### Coating Solution for Fluorine Resin Layer

A first coating solution was prepared by dissolving 70 g of a fluorine resin A and 30 g of a fluorine resin B in 400 g of N,N-dimethyl formamide (DMF) in advance. Separately, 0.6 g of BYK W9010 (manufactured by BYK) and 60 g of titanium dioxide (TiPure TS6200, manufactured by DuPont) were dissolved in 20 g of DMF, and also 100 g of zirconia bead having a diameter of about 0.3 mm was added thereto. Then, the mixture obtained thus was stirred at a speed of 1,000 rpm for 1 hour, and then the bead was removed to prepare a mill base. The mill base was added to the first coating solution, and then stirred to prepare a coating solution for a fluorine resin layer.

Composition for Intermediate Layer

80 g of a urethane aqueous dispersion binder including a siloxane bond (Takelec WS-5000, manufactured by MITSUI, a solid content of 30%) and 20 g of an oxazoline crosslinking agent (Epocros WS-500, manufactured by Nippon Catalyst Co., Ltd., a solid content of 40%) were mixed in water, and then adjusted to be a solid content of 10 wt % to prepare a composition for an intermediate layer.

Preparation of Backsheet

A PET (poly(ethylene terephthalate)) chip that was sufficiently dried was injected to a melting extruder; a PET film was prepared in a T die way; and then the PET film was elongated by about 3.5 times in a mechanical direction at 100° C. to prepare an uniaxial elongated PET film. The composition for the intermediate layer was coated on the uniaxial elongated PET film, appropriately dried at 120° C., and then elongated by about 3.5 times in a transverse direction (that was perpendicular to the mechanical direction). Subsequently, the elongated PET film was subjected to heating at 240° C. for about 10 seconds, and then relaxed by 10% in the mechanical direction and the transverse direction at 200° C. to prepare an intermediate layer having a thickness of about 200 nm. The coating solution for a fluorine resin layer was coated on the intermediate layer in a comma reverse way, such that the thickness after drying was about 20 μm. Since then, the film coated with the coating solution for the fluorine resin layer was sequentially passed through three ovens that had the respective lengths of about 2 m and were respectively controlled at the temperatures of 80° C., 180° C., and 180° C. at a rate of 1 m/min in such order to form a fluorine resin layer. As a result, the backsheet, in which both sides of the PET film (substrate layer) were formed with an intermediate layer and a fluorine resin layer in order of precedence in such a way forming a fluorine resin layer, was prepared.

### Example 2

A backsheet for a photovoltaic module was prepared using the same method as Example 1, except that a urethane aqueous dispersion binder (Takelec WS-5030, manufactured by MITSUI, a solid content of 30%) was used as an aqueous dispersion binder during a process of preparing an aqueous dispersion composition for forming an intermediate layer.

### Example 3

A backsheet for a photovoltaic module was prepared using the same method as Example 1, except that an acrylic-modified polyester aqueous dispersion binder (Pesresin Al24S, manufactured by TAKAMATSU, a solid content of 30%) was used as an aqueous dispersion binder during a process of preparing a coating solution for an intermediate layer.

### Example 4

A backsheet for a photovoltaic module was prepared using the same method as Example 1, except that an acrylic-modified polyester aqueous dispersion binder (Pesresin A645GH, manufactured by TAKAMATSU, a solid content of 30%) and 40 g of an oxazoline crosslinking agent (Epocros WS-700, manufactured by Nippon Catalyst Co., Ltd., a solid content of 25%) were used as an aqueous dispersion binder and a crosslinking agent, respectively, during a process of preparing a coating solution for an intermediate layer.

### Example 5

A backsheet for a photovoltaic module was prepared using the same method as Example 1, except that an acrylic-modified polyester aqueous dispersion binder (Pesresin A645GH, manufactured by TAKAMATSU, a solid content of 30%) and a carbodiimide crosslinking agent (Carbodilite V02-L2, manufactured by Nisshibo, a solid content of 40%) were used as an aqueous dispersion binder and a crosslinking agent, respectively, during a process of preparing a coating solution for an intermediate layer.

### Example 6

A backsheet for a photovoltaic module was prepared using the same method as Example 1, except that 50 g of an acrylic aqueous dispersion binder (Maincoat PR71, manufactured by Rohm and Haas, a solid content of 50%) was used as an aqueous dispersion binder during a process of preparing a coating solution for an intermediate layer.

### Example 7

A backsheet for a photovoltaic module was prepared using the same method as Example 1, except that 8 g of an isocyanate-based crosslinking agent (Duranate WB40-100, manufactured by Asahi Kasei) was used as a crosslinking agent during a process of preparing a coating solution for an intermediate layer.

### Comparative Example 1

A backsheet having the structure laminated with a commercially available Tedlar film, an adhesive, a PET film, an adhesive, and a Tedlar film in order was used as Comparative Example 1. The backsheet was a product, in which a Tedlar film (PVF, a polyvinyl fluoride film (a thickness of 38 μm)) prepared in an extrusion process available from DuPont Inc. was laminated on both sides of the PET film using an adhesive.

### Comparative Example 2

A backsheet having the structure laminated with a commercially available Tedlar film, an adhesive, a PET film, an adhesive, and a Tedlar film in order was used as Comparative Example 2. The backsheet was a product, in which a Tedlar film (a PVF film, a thickness of 25 μm) prepared in a casting process available from DuPont Inc. was laminated on both sides of the PET film using an adhesive.

### Comparative Example 3

A backsheet was prepared using the same method as Example 1, except that a step for forming an intermediate layer was not performed.

### Comparative Example 4

A backsheet for a photovoltaic module was prepared using the same method as Example 1, except that an intermediate layer was formed on the PET film, in which not an inline process but an offline process, that is, an elongation treatment was completed.

### Comparative Example 5

A backsheet for a photovoltaic module was prepared using the same method as Example 6, except that 8 g of polyglycerol polyglycidyl ether (Denacol EX614B, manufactured by Nagase Chemtex), an epoxy compound, was used as a crosslinking agent for the coating solution for an intermediate layer.

In Table 2, compositions included in the intermediate layers of the backsheets for a photovoltaic module in Examples 1 to 7 and Comparative Examples 1 to 5, and contents thereof are listed.

TABLE 2

| | | Composition for intermediate layer | | |
|---|---|---|---|---|
| | | Aqueous | Crosslinking | Thickness of |
| | | dispersion binder | agent | intermediate |
| | | (Content) | (Content) | layer (nm) |
| Example | 1 | WS-5000 (80 g) | WS-500 (20 g) | 200 |
| | 2 | WS-5030 (80 g) | WS-500 (20 g) | 200 |
| | 3 | A124S (80 g) | WS-500 (20 g) | 200 |
| | 4 | A645GH (80 g) | WS-700 (40 g) | 200 |
| | 5 | A645GH (80 g) | V02-L2 (20 g) | 200 |
| | 6 | PR71 (50 g) | WS-500 (20 g) | 200 |
| | 7 | WS-5000 (80 g) | WB40-100 (8 g) | 200 |
| Compar- | 1 | Tedlar(Extrusion)/Adhesive/PET/ | | — |
| ative | | Tedlar(Extrusion) | | |
| Example | 2 | Tedlar(Cast)/Adhesive/PET/Tedlar(Cast) | | — |
| | 3 | — | | — |
| | 4 | WS-5000 (80 g) | WS-500 (20 g) | 200 |
| | 5 | WS-5000 (80 g) | EX614B (8 g) | 200 |

### Test Example 1

For the backsheets for a photovoltaic module in Examples 1 to 7 and Comparative Examples 1 to 5, after performing a pressure cooker test (PCT), a 180° peel strength and cross-hatch test were respectively performed. Specifically, each of the backsheets for a photovoltaic module was maintained under the conditions of 2 atm, 121° C., and 100% R.H. for 25 hours, 50 hours, 75 hours, and 100 hours, respectively, and then the 180° peel strength and cross-hatch test were performed to observe the changes of adhesive strength. The results evaluated thus are listed in the following Table 3.

TABLE 3

| | | 180° peel strength (N/cm) | | | | | Cross-hatch test results | | | | |
|---|---|---|---|---|---|---|---|---|---|---|---|
| | | Initial | 25 hrs | 50 hrs | 75 hrs | 100 hrs | Initial | 25 hrs | 50 hrs | 75 hrs | 100 hrs |
| Example | 1 | Coat-T | Coat-T | Coat-T | Coat-T | Coat-T | 5B | 5B | 5B | 5B | 5B |
| | 2 | Coat-T | Coat-T | Coat-T | Coat-T | Coat-T | 5B | 5B | 5B | 5B | 5B |
| | 3 | Coat-T | Coat-T | Coat-T | Coat-T | Coat-T | 5B | 5B | 5B | 5B | 5B |
| | 4 | Coat-T | Coat-T | Coat-T | Coat-T | Coat-T | 5B | 5B | 5B | 5B | 5B |
| | 5 | Coat-T | Coat-T | Coat-T | Coat-T | Coat-T | 5B | 5B | 5B | 5B | 5B |
| | 6 | Coat-T | Coat-T | Coat-T | Coat-T | Coat-T | 5B | 5B | 5B | 5B | 5B |
| | 7 | Coat-T | Coat-T | Coat-T | Coat-T | Coat-T | 5B | 5B | 5B | 5B | 5B |
| Comparative | 1 | PVF-T | PVF-T | PVF-T | 0 | 0 | 5B | 5B | 5B | 0B | 0B |
| Example | 2 | 6.7 | 4.4 | 1.4 | 0 | 0 | 5B | 5B | 5B | 0B | 0B |
| | 3 | 0 | 0 | 0 | 0 | 0 | 0B | 0B | 0B | 0B | 0B |
| | 4 | Coat-T | Coat-T | Coat-T | 0 | 0 | 5B | 5B | 5B | 0B | 0B |
| | 5 | Coat-T | 0 | 0 | 0 | 0 | 5B | 0B | 0B | 0B | 0B |

Coat-T: It is impossible to measure accurate peel strength since a resin ayer is torn during peeling.
PVF-T: It is impossible to measure accurate peel strength since a PVF film is torn during peeling.

What is claimed is:

1. A backsheet comprising:
a substrate layer;
an intermediate layer which includes an aqueous dispersion binder, and which is formed on the substrate layer; and
a fluorine resin layer formed on the intermediate layer;
wherein after maintaining the backsheet under the conditions of 2 atm, 121° C., and relative humidity of 100% for 75 hours, a peel area according to a cross cut test measured based on ASTM D3002/D3359 is 15% or less with respect to a total area.

2. The backsheet of claim 1, wherein the intermediate layer is an inline coating layer including the aqueous dispersion binder.

3. The backsheet of claim 1, wherein the aqueous dispersion binder is one or more selected from the group consisting of polyurethane, a silane-modified urethane resin, an acrylic resin, polyurea, polyamide, polyolefin, polyvinylacetate, polyether, an alkyd resin, a urethane-acrylate copolymer, a vinyl-urethane copolymer, an ethylene-vinylalcohol copolymer, a silicon-acrylic-urethane copolymer, an ethylene-vinylacetate copolymer, and an acrylic-modified polyester.

4. The backsheet of claim 1, wherein the intermediate layer further includes one or more crosslinking agents selected from the group consisting of an isocyanate crosslinking agent, an oxazoline crosslinking agent, a carbodiimide crosslinking agent, and an aziridine crosslinking agent.

5. The backsheet of claim 4, wherein an aqueous dispersion composition includes 1 part by weight to 300 parts by weight of a crosslinking agent with respect to 100 parts by weight of the aqueous dispersion binder.

6. The backsheet of claim 1, wherein the fluorine resin layer includes a fluorine resin having a degree of crystallinity of 55% or less.

7. The backsheet of claim 6, wherein the fluorine resin has a weight average molecular weight of 50,000 to 1,000,000.

8. The backsheet of claim 6, wherein the fluorine resin has a melting point of 80° C. to 175° C.

9. The backsheet of claim 6, wherein the fluorine resin includes a polymerization unit derived from one or more compounds selected from the group consisting of vinylidene fluoride, vinyl fluoride, tetrafluoroethylene, hexafluoropropylene, chlorotrifluoroethylene, trifluoroethylene, hexafluoroisobutylene, perfluoro(butylethylene), perfluoro(methylvinylether), perfluoro(ethylvinylether), perfluoro(propylvinylether), perfluoro(hexylvinylether), perfluoro-2,2-dimethyl-1,3-dioxol, and perfluoro-2-methylene-4-methyl-1,3-dioxolane.

10. The backsheet of claim 6, wherein the fluorine resin is poly(vinylidene fluoride) or poly(vinyl fluoride) including a polymerization unit derived from one or more comonomers selected from the group consisting of olefin fluoride, alkyl vinyl ether fluoride, perfluoro-2,2-dialkyl-1,3-dioxol, and perfluoro-2-alkylene-4-alkyl-1,3-dioxolane.

11. The backsheet of claim 10, wherein a ratio of the polymerization unit derived from the comonomer is 0.5 wt % to 50 wt % in the total fluorine resin.

12. A method of manufacturing the backsheet of claim 1, the method comprising:
forming an intermediate layer on a substrate layer in an inline coating way; and
forming an fluorine resin layer on the intermediate layer.

13. The method of claim 12, wherein the inline coating way includes elongating the substrate layer in one direction in a state of forming a layer of an aqueous dispersion composition including an aqueous dispersion binder on one side of the substrate layer.

14. The method of claim 13, wherein the substrate layer having the layer of the aqueous dispersion composition is a uniaxial elongated substrate layer, and the substrate layer in a state of forming the layer of the aqueous dispersion composition is elongated in the direction that is perpendicular to the uniaxial elongation direction.

15. The method of claim 13, the method further comprising a relaxation treatment process after performing the elongation.

16. The method of claim 12, wherein the fluorine resin layer is formed by coating a composition including a fluorine resin having a degree of crystallinity of 55% or less and a solvent having a boiling point of 200° C. on the intermediate layer.

17. A photovoltaic module comprising the backsheet of claim 1.
